(19) United States
(12) Patent Application Publication
(10) Pub. No.: US 2006/0076964 A1
(43) Pub. Date: Apr. 13, 2006

(54) Fuel measuring cell

(76) Inventor: Hossein Aghamehdi, Lititz, PA (US)

Correspondence Address: William H. McNeill;OSRAM SYLVANIA Inc., 100 Endicott Street, Danvers, MA, 01923, US

(21) Appl. No.: 10/960,818

(22) Filed: Oct. 7, 2004

(51) Int. Cl. G01R 27/26

(52) U.S. Cl. 324/690

(57) ABSTRACT

A single cell fuel sensor (10) has a housing (12) including only two laterally spaced apart chambers, a first of the chambers (14) being a fuel inlet chamber (15), and a second of the chambers (16) having a fuel mixing portion (18) and a fuel outlet portion (20). The fuel mixing portion (18) and the fuel outlet portion (20) are arrayed along a common axis (22) and an electrode (24) is fitted into the fuel-mixing portion (18) of the second chamber (16). The electrode (24) is electrically isolated from the housing (12) by a glass seal (26).

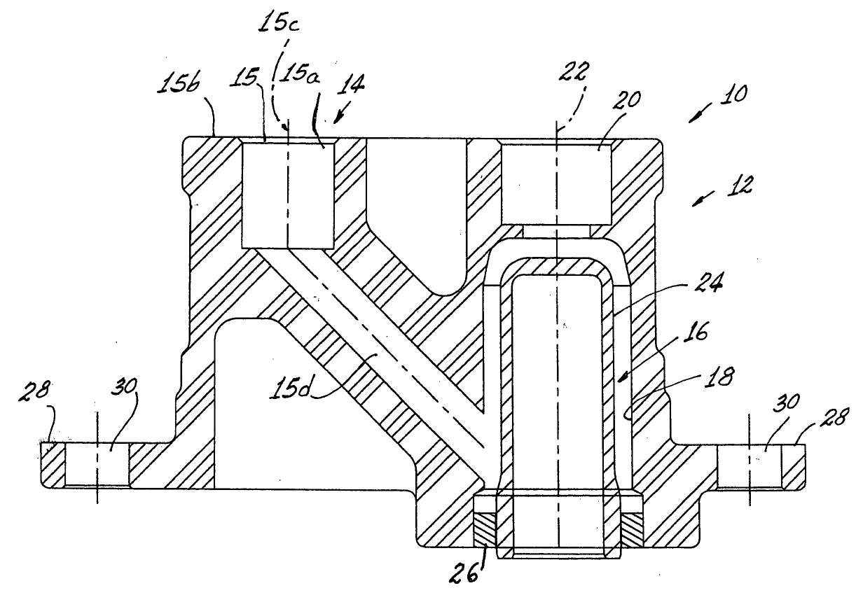

### TECHNICAL FIELD

This invention relates to fuel measuring cells and more particularly to a single cell fuel sensor.

### BACKGROUND ART

Fuel measuring cells generally employ two chambers to generate an electrical measurement of the fuel that resides inside the measuring cell at point in time. The interior of these cells is essentially symmetrical in design. Such cells are used, for example, for measuring the mixture of ethanol and methanol in engines using such a mixture. The cell generates a variable signal that is sent to the engine control module and is based upon the capacitance of the fuel mixture being processed, as measured across certain volumetric gaps inside the cell.

Such cells are complicated and expensive to produce, usually employing machined parts and complicated designs.

A single cell fuel sensor has been proposed that comprises a housing including a fuel inlet chamber, a fuel mixing chamber and a fuel outlet chamber arrayed in a line along three distinct axes. The fuel inlet chamber includes an inlet orifice leading into the mixing chamber at a given level and the fuel outlet chamber includes an outlet orifice leading out of the mixing chamber at a second level that is spaced from the given level. An electrode is fitted into the mixing chamber, and electrically isolated from the housing.

Since the inlet orifice and outlet orifice are at different levels, an asymmetric inlet and outlet orifice arrangement is produced which provides greater fuel mixing and insures that the flow of electrolyte (mixed fuel) fills the electrode area before the fuel is discharged through the outlet orifice. This offset feature also assures the electrolyte (mixed fuel) contacts and wets the maximum possible surface area of the electrode.

This system works well and is described in co-pending patent application Ser. No. 10/796,393, assigned to the assignee of the present invention; however, the lateral spread of the cell caused by the three lateral fuel chambers leaves something to be desired.

### DISCLOSURE OF INVENTION

It is, therefore, an object of the invention to obviate the disadvantages of the prior art.

It is another object of the invention to enhance fuel-measuring cells.

These objects are accomplished, in one aspect of the invention, by the provision of a single cell fuel sensor comprising a housing including only two laterally spaced apart chambers, a first of said chambers being a fuel inlet chamber, and a second of said chambers having a fuel mixing portion and a fuel outlet portion, said fuel mixing portion and said fuel outlet portion being arrayed along a common axis; and an electrode fitted into said fuel mixing portion of said second chamber, said electrode being electrically isolated from said housing.

### BRIEF DESCRIPTION OF THE DRAWINGS

The single FIGURE is an elevational, sectional view of an embodiment of the invention.

### BEST MODE FOR CARRYING OUT THE INVENTION

For a better understanding of the present invention, together with other and further objects, advantages and capabilities thereof, reference is made to the following disclosure and appended claims taken in conjunction with the above-described drawings.

Referring now to the drawings with greater particularity, there is shown in the single FIGURE a single cell fuel sensor 10 that comprises a housing 12 including only two laterally spaced apart chambers. A first of the chambers 14 is a fuel inlet chamber 15, and a second of the chambers 16 has a fuel mixing portion 18 and a fuel outlet portion 20, the fuel mixing portion 18 and the fuel outlet portion 20 being arrayed along a common axis 22. An electrode 24 is fitted into the fuel-mixing portion 18 of the second chamber 16, the electrode 24 being electrically isolated from the housing 12 by a glass seal 26.

In a preferred embodiment of the invention the fuel inlet chamber 15 has an opening 15a in a first surface 15b of the housing 12 centered on an axis 15c and enters the fuel mixing portion 18 of the second chamber 16 at an angle of less than 90° via an intermediate section 15d. Preferably the angle is 45°.

The electrode 24 is cup-shaped and preferably is constructed of metallic materials with thermal expansion characteristics substantially greater than the glass sealing material and capable of sustaining the corrosive environment that occur in mixed fuel conditions. Typical recommended materials are iron-nickel based materials of iron alloys with a protective coating to sustain a corrosive environment

The housing 12 is also preferably provided with ears 28 containing apertures 30 to be used in mounting the sensor 10 in an appropriate position on an engine.

The sensor 10 can be used for measuring the mixture of ethanol and methanol in engines using such a mixture. The sensor operates by sensing the capacitance between the fuel (the electrolyte) and the electrode 24 (the cathode).

The fuel mixture enters the sensor through the fuel inlet chamber 15 and passes through the intermediate section 15d to enter the second chamber 16. The lower or fuel mixing portion 18 of the second chamber 16 receives the fuel mixture which covers the extensive outer surface of the electrode 24 until it egresses through the outlet portion 20. The time period during which the fuel mixture is present in the mixing portion 18 is sufficient for the system to measure the capacitance of the fuel and determine the electrical characteristics of the mixture.

The use of the instant design, in which a single fuel measurement cell is aligned on the same axis as the inlet/outlet, allows a larger contact surface between the measuring cell and the mixed electrolyte, thus improving the accuracy of the electrical characteristics of the electrolyte. Also, weight is reduced, always a critical condition in today's engine environment.

While there have been shown and described what are present considered to be the preferred embodiments of the invention, it will be apparent to those skilled in the art that various changes and modifications can be made herein without departing from the scope of the invention as defined by the appended claims.

1. A single cell fuel sensor comprising:
a housing including only two laterally spaced apart chambers, a first of said chambers being a fuel inlet chamber, and a second of said chambers having a fuel mixing portion and a fuel outlet portion, said fuel mixing portion and said fuel outlet portion being arrayed along a common axis, a major portion of said fuel inlet chamber being inclined at an angle of substantially less than 90° from said common axis of said fuel mixing portion and said fuel outlet portion; and
an electrode fitted into said fuel mixing portion of said second chamber, said electrode being electrically isolated from said housing.

2. (canceled)

3. The single cell fuel sensor of claim 2 wherein said angle of less than 90° is 45°.

4. The single cell fuel sensor of claim 1 wherein said electrode is cup-shaped.

5. The single cell fuel sensor of claim 1 wherein said electrode is electrically isolated from said housing by a glass seal.

6. The single cell fuel sensor of claim 1 wherein said housing is provided with extending ears provided with mounting apertures.
